(19) United States
(12) Patent Application Publication
(10) Pub. No.: US 2009/0160029 A1
(43) Pub. Date: Jun. 25, 2009

(54) Scribe Seal Structure for Improved Noise Isolation

(75) Inventors: Robert L. Pitts, Dallas, TX (US); Thad E. Briggs, Dallas, TX (US); Srinivasan Venkatraman, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/394,216

(22) Filed: Feb. 27, 2009

Related U.S. Application Data
(62) Division of application No. 11/127,007, filed on May 11, 2005.

(51) Int. Cl. H01L 23/00

(52) U.S. Cl. 257/620; 257/E23.194

(57) ABSTRACT

Disclosed is a semiconductor wafer with an array of integrated circuit chips with scribe lane structures forming edge and intra-chip seals for use in protecting the IC circuitry. Substantially parallel scribe seal structures extend around the periphery of each chip; the two scribe seal structures have a separation gap. Preferred embodiments of the invention also include wafers of ICs each having two or more distinctive circuitry blocks such as analog and digital circuitry, separated by an intra-chip seal. Preferred embodiments of also include ICs having two or more distinctive circuit blocks separated by a scribe seal structure with a separation gap and a routing channel for use in passing signals among the circuit blocks.

### TECHNICAL FIELD

The invention relates to semiconductor components, and more particularly, to scribe seal architectures for use in semiconductor components.

### BACKGROUND OF THE INVENTION

In semiconductor electronics, the general trend toward smaller form factors is continuous. In order to reduce form factors, more circuitry must be placed on less wafer real estate. Placing a system containing different types of circuitry on a single chip can reduce form factor and enhance performance. Frequently, system-on-a-chip (SOC) semiconductor devices are used for various applications such as high-speed data transmission and signal processing in wireless and wired systems. As spacing for functional circuit blocks shrinks, however, adjacent circuit blocks may begin to interfere with one another, reducing their performance. Each of the SOC functional blocks may have its own range of power supply conditions and performance requirements. Different power domains may co-exist for digital and analog and RF functional blocks on an integrated chip, for example.

The sharing of a common substrate for different circuit blocks can introduce noise problems. Various efforts to address noise concerns have been used in the arts. For example, it is known to spatially separate circuits in an effort to reduce noise. Other approaches include separating the ground and power supply connections of functional circuit blocks, or placing structures between circuit blocks in order to reduce unwanted current flow.

Generally, numerous semiconductor devices are manufactured using a single semiconductor wafer substrate. The wafer is typically partitioned into individual rectangular dice or chips using scribe streets or lanes. After the layers of circuitry and associated metallic interconnects have been applied to the active regions of the chips, the wafers are sawn along scribe lines to singulate the chips. The chips then undergo further packaging and testing for shipment to customers for inclusion in electronic systems. The sawing process inevitably causes chipping and cracking along the scribe streets. In order to prevent or reduce the propagation of cracks, it is known to design the scribe streets to ensure that the remaining material surrounds the active region of a chip with a scribe seal structure. Multiple layers of metallic and dielectric material are applied laterally adjacent to, or extending across the scribe street for a distance greater than the saw kerf. Alternating metal layers are typically coupled vertically with metal-filled vias and trenches. When the wafer is sawn along the scribe line, a seal structure remains around the edge of each individual chip. It is also known to use a second, inner scribe seal structure around the periphery of each chip, substantially parallel to the outer seal, in order to further isolate the active area from potential physical damage, noise, and ESD events.

In SOC designs, it is known to use an inner guard ring scribe seal structure between functional circuit blocks, such as analog and digital circuit blocks, to segregate the blocks and reduce noise. This approach to noise reduction between the blocks is highly desirable from a manufacturing viewpoint, since no new techniques or process steps are required. The intra-chip scribe seal is prepared as for an inner peripheral seal. However, since the SOC blocks continue to share the same substrate, in some instances noise propagation between the circuit blocks can be a problem.

Due to these and other problems, improved edge and intra-chip scribe seal structures for sealing and separating functional circuit blocks in SOC devices would be useful and advantageous in the arts. Preferably, the technological innovations providing improved scribe seals and circuit block separation would be flexible enough to be applied to various semiconductor product families and would be accomplished using established manufacturing techniques so that substantial investment in new manufacturing processes is not required.

### SUMMARY OF THE INVENTION

In carrying out the principles of the present invention, in accordance with preferred embodiments thereof, scribe lane structures form edge and intra-chip seals for use in protecting semiconductor integrated circuitry.

According to a preferred embodiment, an integrated circuit chip includes two substantially parallel scribe seal structures around the periphery of the chip, the two scribe seal structures having a separation gap.

According to another aspect of the invention, an embodiment of the invention also includes two or more distinctive circuitry blocks such as analog and digital circuitry, separated by an intra-chip seal. The intra-chip seal preferably also includes two substantially parallel scribe seal structures separating the circuit blocks, the two scribe seal structures have a separation gap.

According to yet another aspect of the invention, an integrated circuit having two or more distinctive circuit blocks separated by a scribe seal structure with a separation gap also includes a routing channel for use in passing signals among the circuit blocks.

According to another aspect of the invention, an integrated circuit chip embodiment includes an analog circuitry block and digital circuitry block with an intra-chip scribe seal separating the analog block from the digital block. The intra-chip seal has two substantially parallel scribe seal structures between the circuit blocks with a separation gap. A routing channel is included, coupling the analog block with the digital block for conducting electrical signals between the circuitry blocks.

According to still another aspect of the invention, a semiconductor wafer includes an array of numerous integrated circuit chips, each encompassed by two substantially parallel scribe seal structures at its periphery. The scribe seal structures include a separation gap.

According to another embodiment of the invention, a semiconductor wafer has an array of integrated circuit chips bordered by scribe streets and separated by scribe lines. Each of the integrated circuit chips thereon includes two substantially parallel scribe seal structures at the periphery with a separation gap at the wafer substrate. Each chip also has an analog circuitry block and a digital circuitry block with an intra-chip scribe seal separating the blocks. The intra-chip seal also includes two substantially parallel scribe seal structures between each circuitry block, the two scribe seal structures having a separation gap, and a routing channel coupling the analog block with the digital block for conducting electrical signals between them.

The invention has numerous advantages including but not limited to providing a reliable edge seal and intra-chip seal for inhibiting noise propagation among chip blocks. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a simplified and schematic planar view of an example of a chip embodying the invention;

FIG. 2 is a close-up simplified schematic view of the ESD protection characteristics of the example of the invention shown in FIG. 1;

FIG. 3 is a simplified schematic cross-sectional view of an example of an embodiment of the invention;

FIG. 4 is a simplified schematic cross-sectional view of an example of an alternative embodiment of the invention; and

FIG. 5 a simplified schematic perspective view of an example of a chip embodying the invention.

References in the detailed description correspond to like references in the various figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention relates to semiconductor wafers and to integrated circuit chips constructed using semiconductor wafers. In the preferred embodiments described, a semiconductor wafer includes multiple system-on-chip (SOC) devices, each of which in turn preferably includes two or more distinctive blocks of circuitry, such as an analog block and a digital block.

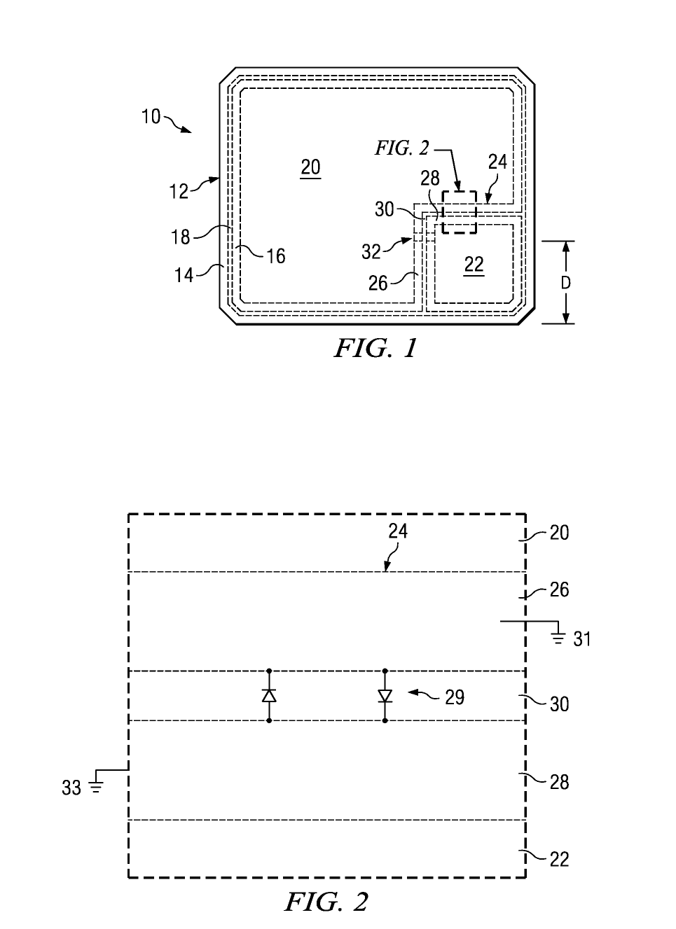

Preferably, a plurality of chips are formed simultaneously on a wafer of semiconductor material. After completion of the fabrication processes, the individual devices are singulated by sawing along scribe lines centered upon the scribe streets. The scribe streets are sufficiently wide to allow for the sacrifice of some material due to the saw kerf, with enough material at the edge of the singulated chip to leave an outer seal about the periphery of the device. FIG. 1 is a simplified planar schematic overview of an example of an individual chip 10 embodying the invention. The periphery of the chip 10 is encompassed by an edge seal 12. The edge seal 12 preferably has an outer structure 14 and an inner structure 16 flanking a separation gap 18 as further described herein. The chip 10 preferably has two or more distinct circuit blocks, in this case a digital block 20 and an analog block 22. An intra-chip seal 24 is positioned between the circuit blocks 20, 22, in order to isolate them from one another. The intra-chip seal 24 preferably has two substantially parallel scribe seal structures 26, 28 at the common borders of the adjacent circuit blocks 20, 22, with a separation gap 30 between them as further described. Preferably, an electrical path 32 is also provided for use in routing signals between the circuit blocks 20, 22.

Protection against damage from electrostatic discharge (ESD) events is preferably provided concurrently with the seals of the invention. As shown in FIG. 2, sensitive circuitry within the sub-chips may be protected from ESD damage by interconnecting the seals 26, 28 with suitable ESD-limiting devices, here represented by anti-parallel substrate diodes 29. Thus, ESD current encountered at either of the seals 26, 28 is substantially diverted across these diodes 29, and providing each with an independent ground 31, 33, respectively, protecting the potentially sensitive circuitry 20, 22. Various ESD-limiting techniques may be used within the scope of the invention as long as arranged to divert the bulk of ESD current to the protection devices connecting the seals dividing sub-circuits.

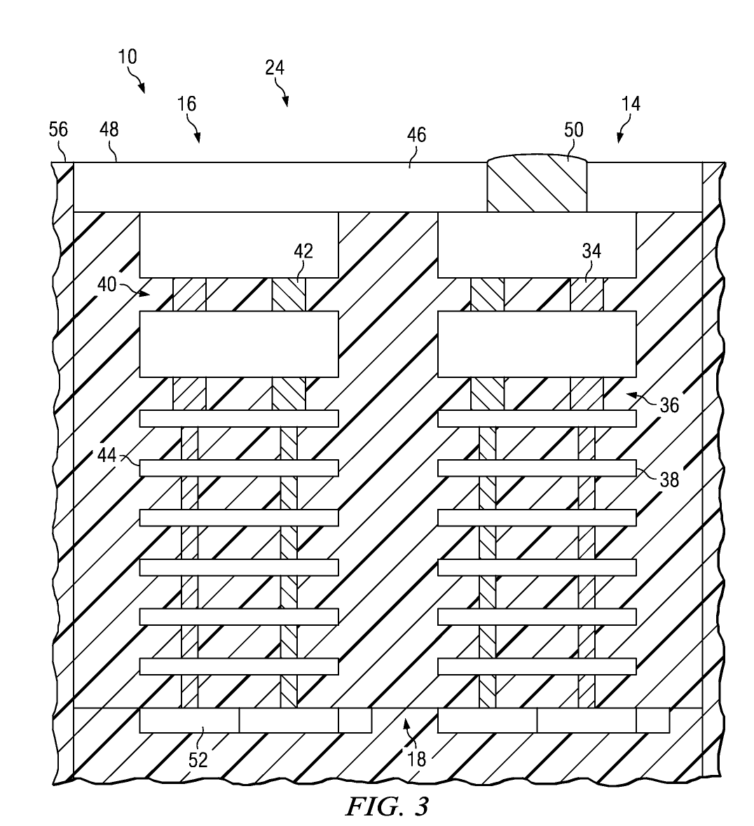

Now referring primarily to FIG. 3, a simplified schematic cross-sectional view of an example of an embodiment of the invention, the chip 10 edge seal 12 is further described. The edge seal 12 embodiment shown has an outer structure 14, preferably with a metal-filled trench 34 and series of metal-filled vias 36 formed in conjunction with successive layers 38 as is known in the arts. A similar configuration is used for the inner structure 16, which is a barrier formed by a filled continuous trench 40, filled vias 42, and successive layers 44. Typically, a passive overcoat 46 is applied to the “top” surface 48 of the chip 10, with contact points 50 exposed as required for contact with the outside world (not shown). At the “bottom” of the chip 10, a semiconductor substrate 52 serves as a foundation. A separation gap 18 is provided between the inner and outer seal structures 14, 16, which run substantially parallel to one another. Preferably, the separation gap 18 is on the order of about 2-3 micrometers wide, although the dimensions may vary according to the application so long as continuous electrical separation 18 of the substrate connections between the outer and inner seal structures 14, 16 is provided. The exact configuration of the outer seal 14 and inner seal 16 structures themselves is not crucial to the implementation of the invention. The introduction of the separation gap 18 between the dual seals 14, 16 of the edge seal structure 12 results in a reduction in noise propagation to the active area 56 of the chip.

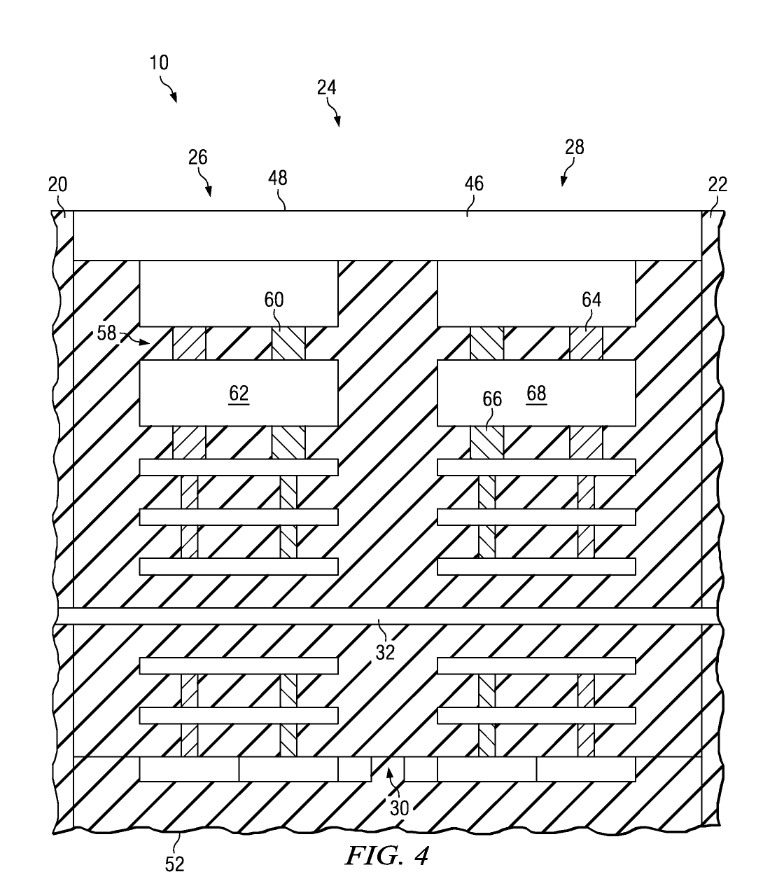

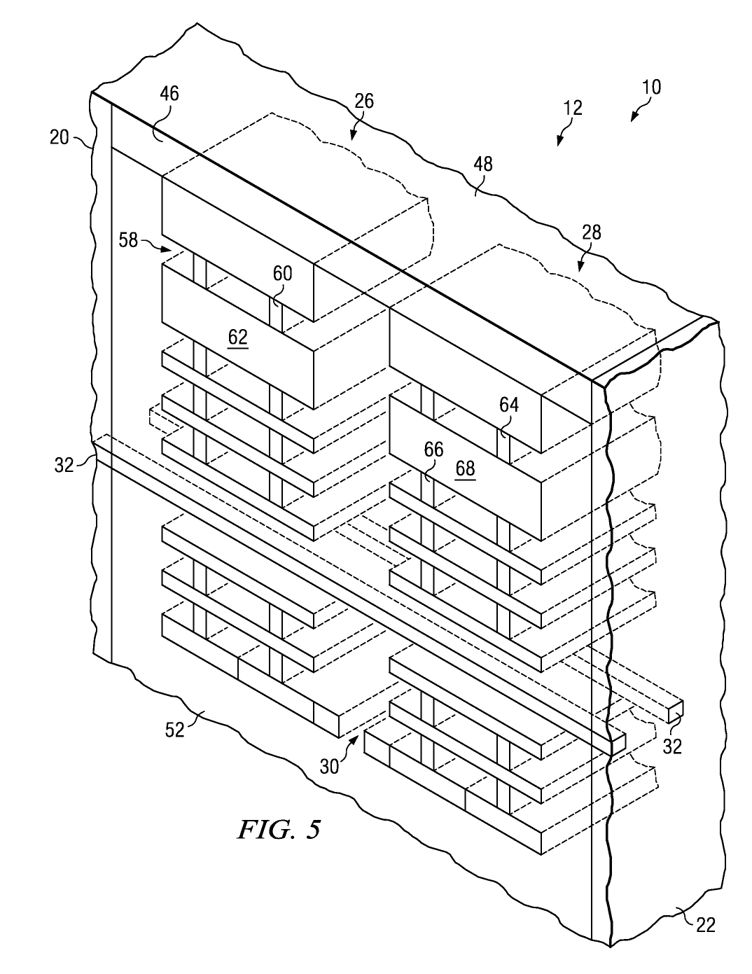

The example of a preferred embodiment of the scribe seal architecture of the invention shown in FIG. 4 shows that the digital 20 and analog 22 circuit blocks of the SOC 10 are segregated by an intra-chip seal structure 24 similar but not identical to the edge seal structure 12. The intra-chip seal structure 24 includes a separation gap 30 at the substrate 52 between the analog and digital circuit blocks 22, 20. An electrical coupling serving as a routing channel 32 is provided between the analog 22 and digital 20 circuitry. Preferably, the routing channel 32 is the sole electrical connection between the circuit blocks 20, 22, and is suitable for use as a signal conduit for passing information, such as control signals, between the circuit blocks 20, 22. Preferably, the routing channel 32 of the intra-chip seal 24 is set back from the edge of the die 10 a distance D (FIG. 1) sufficient to ensure distance-isolation in the event that the edge seal 12 is compromised. With the exception of the inclusion of the routing channel 32 as the sole connection between the digital 20 and analog 22 signal blocks, the intra-chip seal 24 is similar to that of the edge seal 12 described above. The intra-chip seal 24, as shown, has a first structure 26, preferably with a metal-filled trench 58 and series of metal-filled vias 60 formed in conjunction with the successive layers 62 of the chip 10 as is known in the arts. A similar configuration is also used for the inner seal structure 28, which is a barrier formed by a filled continuous trench 64, filled vias 66, and successive layers 68. At the intersecting boundaries of the circuit blocks 20, 22, a separation gap 30 is provided between the first 26 and second 28 seal structures, which preferably run substantially parallel to one another. Preferably, the separation gap 30 is on the order of about 0.5-0.6 micrometers wide in order to prevent interference among the blocks 20, 22, although the dimensions may vary according to the application without departure from the invention. Continuous electrical separation 30 of the substrate connections between the first and second seal structures 26, 28 is provided with the exception of the routing channel 32 provided for the purpose of intra-chip communication. FIG. 5 is a simplified schematic partial perspective view offering an alternative illustration of an example of a chip 10 embodying the invention.

Protection against damage from electrostatic discharge (ESD) events is preferably provided concurrently with the seals of the invention. As shown in FIG. 2, sensitive circuitry within the sub-chips may be protected from ESD damage by interconnecting the seals 26, 28 with suitable ESD-limiting devices, here represented by anti-parallel substrate diodes 29. Thus, ESD current encountered at either of the seals 26, 28 is substantially diverted across these diodes 29 and providing each with an independent ground 31, 33, respectively, protecting the potentially sensitive circuitry 20, 22. Various ESD-limiting techniques may be used within the scope of the invention as long as arranged to divert the bulk of ESD current to the protection devices connecting the seals dividing sub-circuits.

We claim:

1. An integrated circuit chip comprising:
a first circuit block and a second circuit block each occupying a portion of the integrated circuit; and
an intra-chip seal disposed between the first circuit block and the second circuit block comprising first and second independent and substantially parallel scribe seal structures having a separation gap therebetween, the first and second scribe seal structures being separate from such structures on a periphery of the integrated circuit.

2. An integrated circuit chip according to claim 1 wherein each of the substantially parallel scribe seal structures further comprises an independent ground.

3. An integrated circuit chip according to claim 1 further comprising an ESD protection circuit coupling the substantially parallel scribe seal structures.

4. An integrated circuit chip according to claim 1 further comprising a routing channel in the intra-chip seal for passing signals between the circuit blocks.

5. An integrated circuit chip according to claim 1 wherein one of the circuitry blocks comprises primarily analog circuitry.

6. An integrated circuit chip according to claim 1 wherein one of the circuitry blocks comprises primarily RF circuitry.

7. An integrated circuit chip according to claim 1 wherein one of the circuitry blocks comprises primarily digital circuitry.

8. An integrated circuit chip comprising:
an analog circuitry block and a digital circuitry block;
an intra-chip scribe seal separating the analog block from the digital block, the intra-chip seal further comprising;
two substantially parallel scribe seal structures at the common boundary of the circuitry blocks, the two scribe seal structures having a separation gap at the inner seal; and
a routing channel above the substrate level and coupling the analog block with the digital block for conducting electrical signals between the circuitry blocks.

9. An integrated circuit chip according to claim 8 wherein each of the substantially parallel scribe seal structures further comprises an independent ground.

10. An integrated circuit chip according to claim 8 further comprising an ESD protection circuit coupling the substantially parallel scribe seal structures.

11. A semiconductor wafer comprising:
an array of integrated circuit chips bordered by scribe streets and separated by scribe lines;
two substantially parallel scribe seal structures at the periphery of each chip, the two scribe seal structures having a separation gap in the inner seal.

12. A semiconductor wafer comprising:
an array of integrated circuit chips bordered by scribe streets and separated by scribe lines, each integrated circuit chip further comprising;
two substantially parallel scribe seal structures at the periphery of each chip, the two scribe seal structures having a separation gap in the inner seal;
an analog circuitry block and a digital circuitry block;
an intra-chip scribe seal separating the analog block from the digital block, the intra-chip seal further comprising;
two substantially parallel scribe seal structures at the common boundary of each circuitry block, the two scribe seal structures having a separation gap in the inner seal; and
a routing channel above the substrate level and coupling the analog block with the digital block for conducting electrical signals between the circuitry blocks.

13. A semiconductor wafer according to claim 12 wherein each of the substantially parallel scribe seal structures further comprises an independent ground.

14. A semiconductor wafer according to claim 12 further comprising an ESD protection circuit coupling the substantially parallel scribe seal structures.

15. A semiconductor wafer according to claim 12 wherein one of the circuitry blocks comprises primarily RF circuitry.

16. An integrated circuit chip comprising:
a semiconductor substrate having first and second circuit blocks formed thereon, each of the first and second circuit blocks occupying a portion of the substrate;
a first scribe seal structure formed on a periphery of the substrate along a scribe line for singulating the integrated circuit chip from a wafer comprising a plurality of integrated circuit chips; and
an intra-chip seal formed on the substrate between the first and second circuit blocks comprising an additional scribe seal structure having second and third substantially parallel scribe seal structures, each independent of the other and having a separation gap therebetween, the second and third scribe seal structures being an extension of the first scribe seal structure.

17. The integrated circuit chip of claim 16 wherein the first scribe seal structure comprises a pair of independent and substantially parallel scribe seal structures having a separation gap therebetween.
